(19) United States
(12) Patent Application Publication
(10) Pub. No.: US 2026/0334018 A1
(43) Pub. Date: Oct. 22, 2026

(54) DISPLAY PANEL, ELECTRONIC DEVICE, AND METHOD OF MANUFACTURING DISPLAY PANEL

(71) Applicant: Samsung Display Co., Ltd., Yongin-si (KR)

(72) Inventors: Youngmin MOON, Yongin-si (KR); Arong KIM, Yongin-si (KR); Jaeik KIM, Yongin-si (KR); Hee Jun YANG, Yongin-si (KR); Samin LEE, Yongin-si (KR)

(73) Assignee: Samsung Display Co., Ltd., Yongin-si (KR)

(21) Appl. No.: 19/639,970

(22) Filed: Apr. 6, 2026

(30) Foreign Application Priority Data
Apr. 18, 2025 (KR) 10-2025-0050752

(51) Int. Cl. H10K 59/122; G06F 3/01; H10K 59/12; H10K 59/60; H10K 59/80; H10K 59/88

(52) U.S. Cl. CPC H10K 59/122; H10K 59/1201; H10K 59/60; H10K 59/873; H10K 59/88; G06F 3/017

(57) ABSTRACT

A display panel may include a first pixel defining film on a base layer and including a first light emitting opening, a first light emitting element, an inorganic layer covering the first light emitting element, a second pixel defining film on the inorganic layer and including a second light emitting opening, a partition wall on the second pixel defining film and including a partition wall opening overlapping the second light emitting opening, and a second light emitting element. The first light emitting element may include a first anode on the base layer, a first light emitting pattern in the first light emitting opening, and a first cathode on the first light emitting pattern. The second light emitting element may include a second anode on the inorganic layer, a second light emitting pattern in the second light emitting opening, and a second cathode in contact with the partition wall.

### CROSS-REFERENCE TO RELATED APPLICATIONS

This application claims priority under 35 U.S.C. § 119 to Korean Patent Application No. 10-2025-0050752, filed on Apr. 18, 2025 in the Korean Intellectual Property Office, the entire disclosure of which is incorporated by reference herein.

### BACKGROUND

### 1. Field

Embodiments of the present disclosure described herein relate to a display panel, an electronic device, and a method of manufacturing a display panel, and more particularly, relate to a display panel having improved display quality, an electronic device, and a method of manufacturing a display panel.

### 2. Description of Related Art

A display device, such as a television, a monitor, a smartphone, and a tablet PC, may provide an image to a user and may include a display panel that displays an image. Various display panels, such as liquid crystal display panels, organic light emitting display panels, electrowetting display panels, and electrophoretic display panels as display panels, are being developed.

The organic light emitting display panel may include an anode, a cathode, and a light emitting pattern. The light emitting pattern may be separated for each light emitting area, and the cathode may provide a common voltage to each light emitting area.

### SUMMARY

Embodiments of the present disclosure provide a display panel, an electronic device, and/or a method of manufacturing a display panel, in which at least some of the light emitting elements are formed without using a metal mask, thereby improving display quality.

According to an embodiment, a display panel may include a base layer, a first pixel defining film on the base layer and including a first light emitting opening, a first light emitting element, an inorganic layer covering the first light emitting element, a second pixel defining film on the inorganic layer and including a second light emitting opening, a partition wall on the second pixel defining film and including a partition wall opening overlapping the second light emitting opening, and a second light emitting element. The first light emitting element may include a first anode on the base layer, a first light emitting pattern in the first light emitting opening, and a first cathode on the first light emitting pattern. The second light emitting element may include a second anode on the inorganic layer, a second light emitting pattern in the second light emitting opening, and a second cathode in contact with the partition wall.

According to an embodiment, an electronic device may include a display panel configured to display an image; and a processor configured to provide image data to the display panel. The display panel may include: a base layer; a first pixel defining film on the base layer and including a first light emitting opening; a first light emitting element including a first anode on the base layer, a first light emitting pattern in the first light emitting opening, and a first cathode on the first light emitting pattern; an inorganic layer covering the first light emitting element; a second pixel defining film on the inorganic layer and including a second light emitting opening; a partition wall on the second pixel defining film and including a partition wall opening overlapping the second light emitting opening; and a second light emitting element including a second anode on the inorganic layer, a second light emitting pattern in the second light emitting opening, and a second cathode in contact with the partition wall.

According to an embodiment, a method of manufacturing a display panel may include forming a first anode and a sub-anode on a base layer; forming a first pixel defining film that exposes the first anode and the sub-anode; forming a first light emitting pattern and a first cathode on the first anode; forming an inorganic layer on the sub-anode, the inorganic layer including a contact hole through which at least a portion of the sub-anode may be exposed; forming a second anode electrically connected to the sub-anode through the contact hole of the inorganic layer; forming a second pixel defining film on the second anode, the second pixel defining film exposing the second anode; forming a partition wall on the second pixel defining film, the partition wall including a partition wall opening overlapping the second anode; and forming a second light emitting pattern and a second cathode in the partition wall opening. The second cathode may be in contact with the partition wall.

### BRIEF DESCRIPTION OF THE DRAWINGS

The above and other objects and features of the present disclosure will become apparent by describing in detail embodiments thereof with reference to the accompanying drawings.

FIG. 1 is a block diagram of an electronic device according to an embodiment of the present disclosure.

FIG. 2 is a schematic view illustrating various electronic devices according to an embodiment.

FIG. 3 is a perspective view of the electronic device according to an embodiment of the present disclosure.

FIG. 4 is an exploded perspective view of the electronic device according to an embodiment of the present disclosure.

FIGS. 5A and 5B are cross-sectional views of a display device corresponding to line I-I′ of FIG. 4 according to an embodiment of the present disclosure.

FIG. 6 is a plan view of a display panel according to an embodiment of the present disclosure.

FIG. 7 is a plan view of an input sensing layer according to an embodiment of the present disclosure.

FIG. 8 is an enlarged plan view of a portion of a display area of the display panel according to an embodiment of the present disclosure.

FIG. 9 is a cross-sectional view of the display panel corresponding to line II-II′ of FIG. 8 according to an embodiment of the present disclosure.

FIG. 10 is a cross-sectional view of the display panel corresponding to line III-III′ of FIG. 8 according to an embodiment of the present disclosure.

FIG. 11 is a cross-sectional view of a portion of the display panel according to an embodiment of the present disclosure.

FIG. 12A is an enlarged plan view of a portion of the display area of the display panel according to an embodiment of the present disclosure.

FIG. 12B is a cross-sectional view of the display device corresponding to line IV-IV′ illustrated in FIG. 12A according to an embodiment of the present disclosure.

FIGS. 13A to 13J are cross-sectional views illustrating some of operations of a method of manufacturing a display panel according to an embodiment of the present disclosure.

### DETAILED DESCRIPTION

Since example embodiments of the present disclosure may be variously modified and may be various forms, only some embodiments will be illustrated in the drawings and will be described herein in detail. However, it should be understood that embodiments of the present disclosure are not limited to the presented embodiments and may includes all changes, equivalents, and substitutes included in the spirit and scope of the present disclosure.

In the specification, the expression that a first component (or area, layer, part, portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first,” “second,” etc., may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

In the specification, the wording “directly disposed” may mean that there is no layer, no film, no area, no plate, and the like added between a part such as a layer, a film, an area, and a plate, and other parts. For example, the expression “directly arranged” may mean that two layers or two members are arranged without an additional member such as an adhesive member therebetween.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, a display device according to an embodiment will be described with reference to the accompanying drawings.

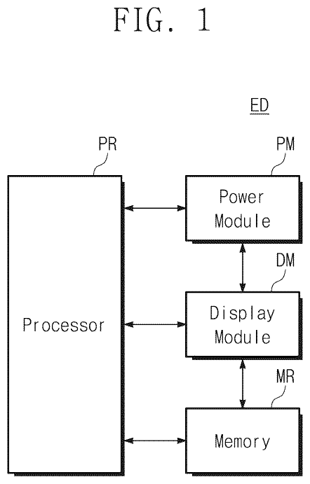

FIG. 1 is a block diagram of an electronic device according to an embodiment of the present disclosure.

Referring to FIG. 1, an electronic device ED according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), and a controller.

Data information may be required for operating the processor PR and/or the display module DM and may be stored in the memory MR. When the processor PR executes an application stored in the memory MR, an image data signal and/or an input control signal may be transmitted to the display module DM, and the display module DM may process the received signal and output image information through the display screen. The display module DM may include a display panel that displays an image.

The power module PM may include a power conversion module. The power conversion module may be a power supply module such as a power adapter or a battery device and convert power supplied by the power supply module to generate power required for operating the electronic device ED.

At least one of the components of the electronic device ED may be included in a display module according to an embodiment, which will be described below, and a display device including the same according to an embodiment. Further, some individual modules, which functionally may be included inside one module, may be included inside the display device, and the others thereof may be provided separately from the display device. For example, the display device may include the display module DM, and the processor PR, the memory MR, and the power module PM may be provided in the form of other devices in the electronic device ED rather than the display device.

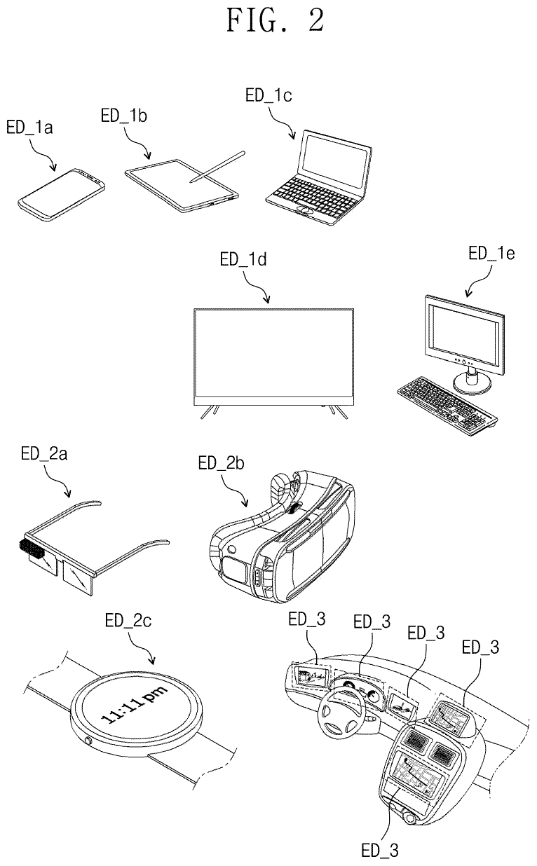

FIG. 2 is a schematic view illustrating various electronic devices according to an embodiment.

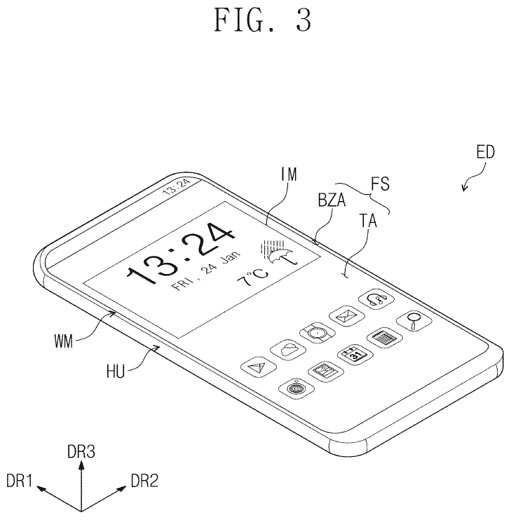

Referring to FIG. 2, various electronic devices including the display module according to an embodiment may include an image display electronic device such as a smartphone ED_1a, a tablet PC ED_1b, a laptop computer ED_1c, a television (TV) ED_1d, and a desk monitor ED_1e, a wearable electronic device such as a smart glasses ED_2a, a head mounted display ED_2b, and a smart watch ED_2c, and a vehicle electronic device ED_3 such as an instrument panel, a center fascia, a center information display (CID) disposed on a dashboard, and a room mirror display of a vehicle. The electronic device ED according to an embodiment of the present disclosure may be a mobile phone as illustrated in FIG. 3, but the present disclosure is not limited thereto.

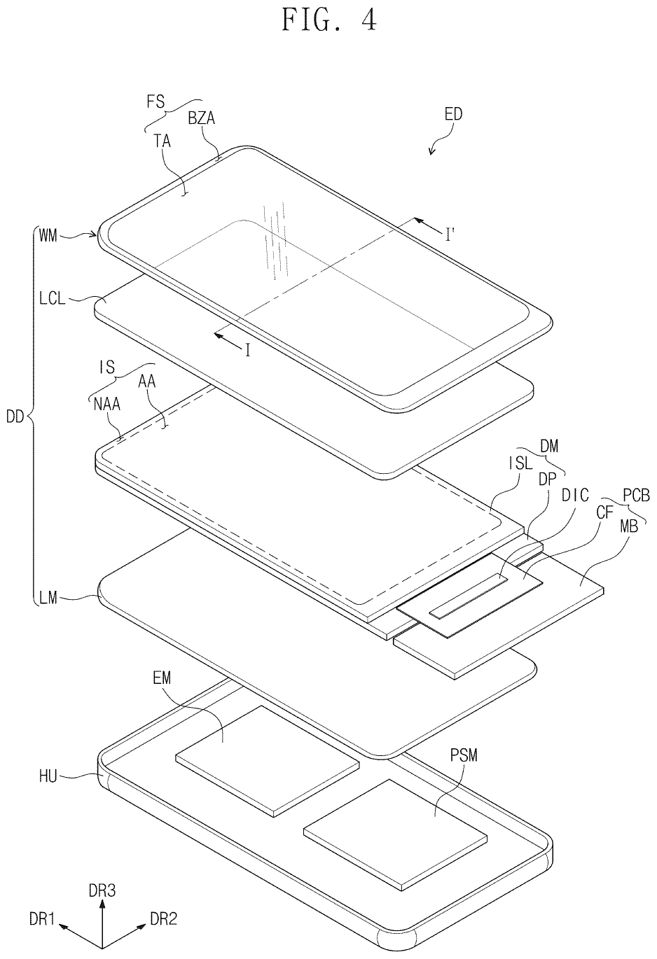

FIG. 3 is a perspective view of the electronic device according to an embodiment of the present disclosure. FIG. 4 is an exploded perspective view of the electronic device according to an embodiment of the present disclosure.

The electronic device ED may be a device that is activated according to an electrical signal. The electronic device ED may include an embodiment. For example, the electronic device ED may be applied to electronic devices such as mobile phones, smart watches, tablets, laptops, computers, and smart televisions. The display device of the present disclosure is not limited to the above examples and may be adopted in other electronic devices without departing from the concepts of the present disclosure. In an embodiment, the electronic device ED illustrates, by way of example, a mobile phone.

The electronic device ED may display an image IM in a third direction DR3 on a display surface FS parallel to a first direction DR1 and a second direction DR2. The display surface FS on which the image IM is displayed may correspond to a front surface of a display device DD. The image IM may include a still image as well as a dynamic image. FIG. 3 illustrates a clock and icons as an example of the image IM.

In an embodiment, a front surface (or an upper surface) and a rear surface (or a lower surface) of each member are defined with respect to a direction in which the image IM is displayed. The front surface and the rear surface may be opposite to each other in the third direction DR3, and a normal direction of each of the front surface and the rear surface may be parallel to the third direction DR3. A separation distance between the front surface and the rear surface in the third direction DR3 may correspond to a thickness of the display device DD in the third direction DR3. In the specification. the wording “on a plane” may mean a state when viewed in the third direction DR3. The directions indicated by the first direction DR1, the second direction DR2, and the third direction DR3 are relative concepts and may be changed to other directions.

The electronic device ED may sense an external input applied from the outside. The external input may include various types of inputs provided from the outside of the electronic device ED. For example, the external input may include a contact by a part of a body of the user such as a hand as well as an external input (for example, hovering) applied close to the electronic device ED or adjacent to the electronic device ED at a predetermined distance. Further, the external input may have various forms such as a force, a pressure, a temperature, and light.

The electronic device ED may include a window WM and a housing HU. The window WM and the housing HU may be coupled to form an external appearance of the electronic device ED.

The window WM may be divided into a transmissive area TA and a bezel area BZA. The front surface of the electronic device ED may correspond to the transmissive area TA and the bezel area BZA of the window WM.

The transmissive area TA may be an area on which the image IM is displayed. The transmissive area TA may be an optically transparent area. The user may visually recognize the image IM through the transmissive area TA.

In an embodiment, the transmissive area TA is illustrated as a quadrangular shape having rounded vertexes. However, this is illustrated by way of example, the transmissive area TA may have various shapes, and the present disclosure is not limited to an embodiment.

The bezel area BZA may be an area having a relatively low light transmittance as compared to the transmissive area TA. For example, the bezel area BZA may be provided as an area on which a material having a predetermined color is printed.

The bezel area BZA may be an area adjacent to the transmissive area TA. The bezel area BZA may surround the transmissive area TA. Accordingly, a shape of the transmissive area TA may be substantially defined by the bezel area BZA. However, this is illustrated by way of example, and the bezel area BZA may be disposed adjacent to only one side of the transmissive area TA or may be omitted.

Referring to FIGS. 3 and 4 together, the electronic device ED may include the display device DD, an electronic module EM, a power supply module PSM, and the housing HU. FIG. 4 schematically illustrates the electronic device ED, and the electronic device ED may further include a mechanical structure (e.g., a hinge) for controlling an operation (e.g., folding or rolling) of the display device DD.

The display device DD includes the window WM, a light control layer LCL, the display module DM, a lower member LM, a driving chip DIC, and a printed circuit board PCB. The display module DM may include a display panel DP and an input sensing layer ISL.

The window WM may be disposed on the display module DM. The window WM may protect the display module DM. The window WM may include an optically transparent material. For example, the window WM may include glass, sapphire, plastic, or the like. An image provided on the display module DM may be provided to the user through the window WM.

The window WM may have a single-layer structure or a multi-layer structure. For example, the window WM may include a plurality of plastic films coupled to each other or a glass substrate and a plastic film coupled to each other.

The light control layer LCL may control a path of light generated by the display panel DP. The light control layer LCL may condense light provided from the display panel DP or may further spread light generated in a partial area of the display panel DP. A detailed description of the light control layer LCL will be provided below.

The display module DM may include a front surface IS including an active area AA and a peripheral area NAA. The active area AA may be an area that is activated according to an electric signal. In an embodiment, the active area AA may be an area on which the image IM is displayed, and at the same time, may be an area in which the external input is sensed.

The transmissive area TA may overlap at least a portion of the active area AA. Accordingly, the user may visually recognize the image IM or provide the external input, through the transmissive area TA. However, this is illustrated by way of example, an area in which the image IM is displayed and an area in which the external input is sensed may be separated from each other inside the active area AA, and the present disclosure is not limited to an embodiment.

The peripheral area NAA may be an area covered by the bezel area BZA. The peripheral area NAA is adjacent to the active area AA. The peripheral area NAA may surround the active area AA. A driving circuit or a driving wiring line for driving the active area AA may be disposed in the peripheral area NAA.

The display panel DP according to an embodiment of the present disclosure may be a liquid crystal display panel or a light emitting display panel, but the present disclosure is not particularly limited thereto. For example, the light emitting display panel may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod.

The display panel DP may be flexible. The wording “flexible” may mean a bendable property and include a completely folded structure to a structure that may be partially bent. For example, the display panel DP may be a curved display panel or a foldable display panel. The present disclosure is not limited thereto, and the display panel DP may be rigid.

The input sensing layer ISL may be disposed on the display panel DP. As illustrated in FIG. 4, the input sensing layer ISL may be directly disposed on the display panel DP. That is, the input sensing layer ISL may be formed on the display panel DP by a continuous process, and an adhesive film may not be disposed between the input sensing layer ISL and the display panel DP. However, the present disclosure is not limited thereto, and the adhesive film may be disposed between the input sensing layer ISL and the display panel DP. The input sensing layer ISL may be manufactured through a separate process from the display panel DP and then fixed to an upper surface of the display panel DP by the adhesive film.

The input sensing layer ISL may detect an external input applied from the outside. As described above, the input sensing layer ISL may sense the external input provided on the window WM.

The printed circuit board PCB may be disposed on one side of the display panel DP. The printed circuit board PCB may include a connection circuit board CF and a main circuit board MB.

The connection circuit board CF may connect the display panel DP and the main circuit board MB. The connection circuit board CF may be electrically connected to the display panel DP on one side adjacent to the display panel DP. The connection circuit board CF may be electrically connected to the main circuit board MB on the other side adjacent to the main circuit board MB.

The one connection circuit board CF connecting the display panel DP and the main circuit board MB is illustrated in an embodiment, but the present disclosure is not limited thereto, and the connection circuit board CF may be provided as a plurality of connection circuit boards CF, which may connect the display panel DP and the main circuit board MB.

The connection circuit board CF may be a flexible printed circuit board that is flexible. The connection circuit board CF may provide an electrical signal for driving the display panel DP to the display panel DP. The electrical signal may be generated in the connection circuit board CF or may be generated in the main circuit board MB.

The driving chip DIC may be mounted on the connection circuit board CF. The driving chip DIC may be mounted on the flexible printed circuit board to constitute a chip on film (COF). The driving chip DIC may include driving elements for driving pixels of the display panel DP. The driving chip DIC may include a driving circuit, and the driving circuit may include an integrated circuit. The driving circuit may include a driving controller, a data driver, a voltage generator, and the like.

The main circuit board MB may include a main controller. The main circuit board MB may include signal wiring lines (not illustrated) for transmitting control signals and image signals received from the main controller to the connection circuit board CF and the display panel DP.

Although not illustrated, the printed circuit board PCB may further include an input circuit board electrically connected to the input sensing layer ISL. The input circuit board may connect the input sensing layer ISL to the main circuit board MB. In an embodiment, the input circuit board may be provided as a flexible circuit film and may connect the input sensing layer ISL and the main circuit board MB. The input circuit board provides an electrical signal for driving the input sensing layer ISL to the input sensing layer ISL. The electrical signal may be generated by the input circuit board or may be generated by the main circuit board MB.

Each of the connection circuit board CF and the input circuit board may be connected to the one main circuit board MB. One of the connection circuit board CF and the input circuit board may not be connected to the main circuit board MB, but the present disclosure is not limited to an embodiment.

The lower member LM may be disposed under the display panel DP. The lower member LM may include a protective film that protects the display panel DP, a support member that supports the display panel DP, a digitizer, and the like.

The electronic module EM and the power supply module PSM may be arranged under the display module DM. The electronic module EM and the power supply module PSM may be electrically connected through a separate circuit board.

The power supply module PSM may supply power required for operating of the electronic device ED. For example, the power supply module PSM may include a general battery module.

The electronic module EM may include a control module, a wireless communication module, an image input module, a sound input module, a sound output module, a memory, an external interface module, and the like. The electronic module EM may include the main circuit board, and the modules may be mounted on the main circuit board MB or may be electrically connected to the main circuit board MB through the flexible circuit board. The electronic module EM is electrically connected to the power supply module PSM.

Although not separately illustrated, the electronic device ED may further include an electro-optical module. The electro-optical module may be an electronic component that outputs or receives an optical signal. The electro-optical module may include a camera module and/or a proximity sensor. The camera module may capture an external image through a partial area of the display panel DP.

The housing HU illustrated in FIG. 4 is coupled to the display device DD, particularly, the window WM, and accommodates the other modules. It is illustrated that the housing HU has an integral shape, but the present disclosure is not limited thereto. The housing HU may include a plurality of portions (e.g., a side edge portion and a bottom portion) coupled to each other. The housing HU may protect the display module DM accommodated in an inner space from an external impact and may prevent foreign substances or moisture from penetrating into the display module DM.

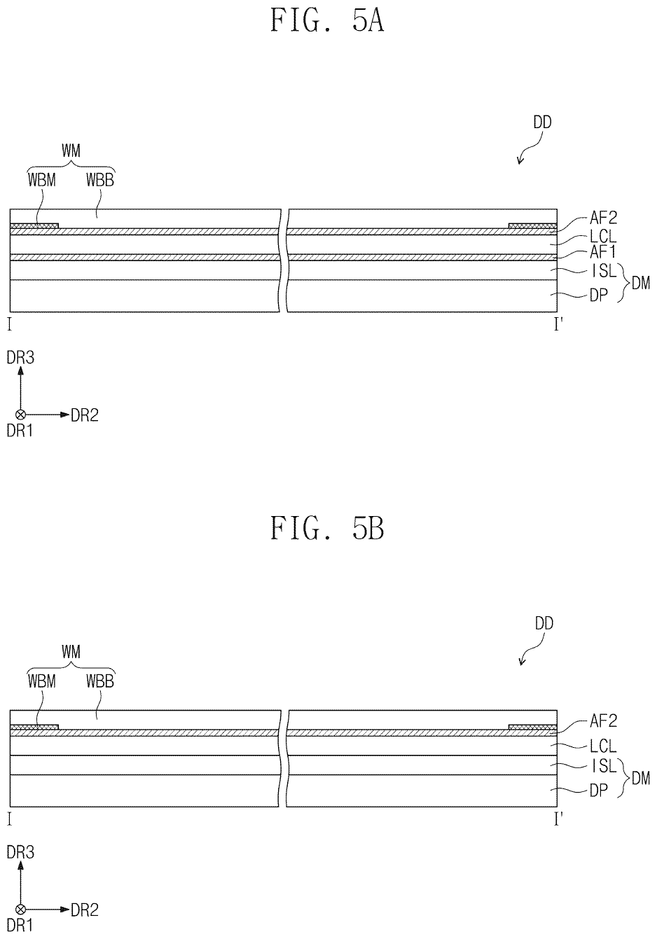

FIGS. 5A and 5B are cross-sectional views of a display device corresponding to line I-I′ of FIG. 4 according to an embodiment of the present disclosure. FIGS. 5A and 5B schematically illustrate an embodiment according to a laminated form of components of the display device DD. The above description may be equally applied to the components of the display device DD illustrated in FIGS. 5A and 5B.

Referring to FIGS. 5A and 5B, the window WM according to an embodiment may include a base substrate WBB and a bezel pattern WBM. The base substrate WBB may include an optically transparent insulating material. The base substrate WBB may include at least one of a glass substrate and a synthetic resin film. The base substrate WBB may have a single-layer structure or a multi-layer structure. Meanwhile, functional layers such as a fingerprint preventing layer, an optical layer that controls a phase, and a hard coating layer may be further disposed on the base substrate WBB.

The bezel pattern WBM may be a color layer formed on one surface of the base substrate WBB. The bezel pattern WBM may have a single-layer or multi-layer structure. The multi-layer bezel pattern WBM may include a chromatic color layer and an achromatic (particularly, black) light shielding layer. The bezel pattern WBM may be formed on the base substrate WBB through a deposition process, a printing process, or a coating process. An area in which the bezel pattern WBM is disposed may substantially correspond to the bezel area BZA of the window WM.

Referring to FIG. 5A, the window WM and the light control layer LCL may be coupled to a component disposed at a lower portion thereof through adhesive layers AF1 and AF2. The light control layer LCL may adhere to the display module DM through the first adhesive layer AF1. In detail, the light control layer LCL may be fixed onto an upper surface of the input sensing layer ISL through the first adhesive layer AF1. The window WM may adhere onto the light control layer LCL through the second adhesive layer AF2.

Each of the first adhesive layer AF1 and the second adhesive layer AF2 may include a transparent adhesive such as an optically clear adhesive film (OCA), an optically clear resin (OCR), or a pressure sensitive adhesive film (PSA). However, the types of the first adhesive layer AF1 and the second adhesive layer AF2 are not limited to the above example.

Referring to FIG. 5B, the light control layer LCL may be directly disposed on the display module DM. In detail, the light control layer LCL may be formed on the input sensing layer ISL through a continuous process. For example, the light control layer LCL may be formed by applying (or printing) and patterning a composition of a color filter on a base surface provided by the input sensing layer ISL. As the light control layer LCL is integrated and disposed on the display module DM, the first adhesive layer AF1 of FIG. 5A may be omitted.

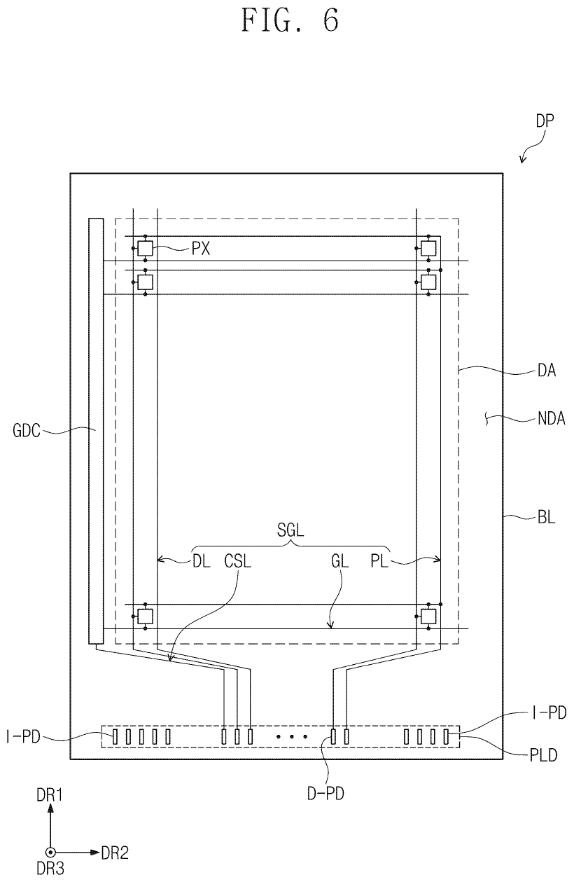

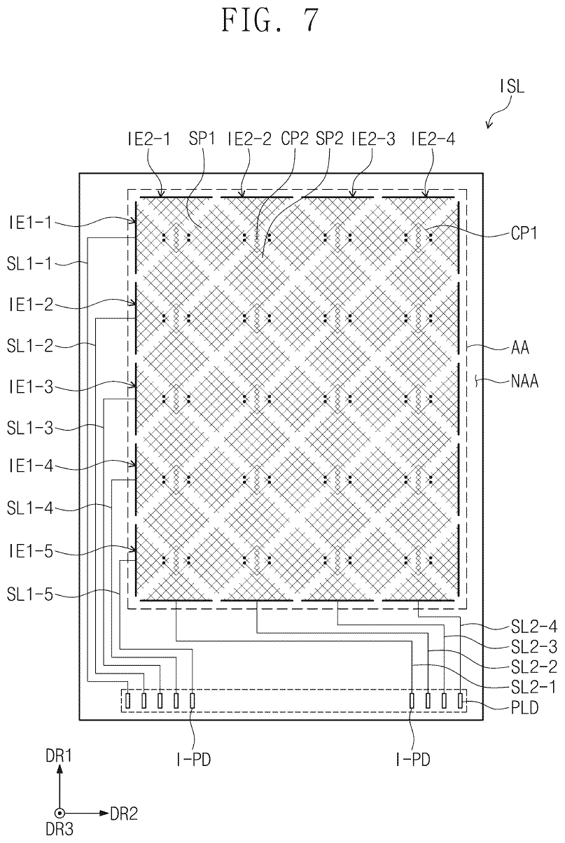

FIG. 6 is a plan view of a display panel according to an embodiment of the present disclosure, and FIG. 7 is a plan view of an input sensing layer according to an embodiment of the present disclosure.

Referring to FIG. 6, the display panel DP may include a base layer BL divided into a display area DA and a non-display area NDA. The display panel DP may include pixels PX arranged in the display area DA and signal lines SGL electrically connected to the pixels PX. The display panel DP may include a driving circuit GDC and a pad part PLD arranged in the non-display area NDA.

Each of the pixels PX may include a light emitting element, which will be described below, and a pixel driving circuit connected thereto. The signal lines SGL may include gate lines GL, data lines DL, a power line PL, and a control signal line CSL. Each of the gate lines GL may be connected to a corresponding one of the pixels PX, and each of the data lines DL may be connected to a corresponding one of the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to the pixel driving circuit.

The pad part PLD may be a part to which the connection circuit board CF of FIG. 4 is connected. The pad part PLD may include pixel pads D-PD and input pads I-PD. The pixel pads D-PD may be pads for connecting the connection circuit board CF to the display panel DP. The input pads I-PD may be pads for connecting the connection circuit board CF to the input sensing layer ISL.

Each of the pixel pads D-PD may be connected to a corresponding one of the signal lines SGL. Each of the pixel pads D-PD may be connected to a corresponding pixel PX through the signal line SGL. Further, any one pixel pad among the pixel pads D-PD may be connected to the driving circuit GDC.

Referring to FIG. 7, the input sensing layer ISL may be divided into the active area AA and the peripheral area NAA. The active area AA may correspond to the display area DA illustrated in FIG. 6, and the peripheral area NAA may correspond to the non-display area NDA illustrated in FIG. 6.

The input sensing layer ISL according to an embodiment may include a plurality of sensing electrodes and a plurality of signal lines. The input sensing layer ISL may include first sensing electrodes IE1-1 to IE1-5 and second sensing electrodes IE2-1 to IE2-4. The input sensing layer ISL may include first signal lines SL1-1 to SL1-5 connected to the first sensing electrodes IE1-1 to IE1-5 and second signal lines SL2-1 to SL2-4 connected to the second sensing electrodes IE2-1 to IE2-4.

The first sensing electrodes IE1-1 to IE1-5 and the second sensing electrodes IE2-1 to IE2-4 may intersect each other. The first sensing electrodes IE1-1 to IE1-5 may extend in the second direction DR2 and may be arranged in the first direction DR1. The second sensing electrodes IE2-1 to IE2-4 may extend in the first direction DR1 and may be arranged in the second direction DR2. The first sensing electrodes IE1-1 to IE1-5 and the second sensing electrodes IE2-1 to IE2-4 may be electrodes electrically insulated from each other.

The first signal lines SL1-1 to SL1-5 and the second signal lines SL2-1 to SL2-4 may be arranged in the non-display area NDA. The first signal lines SL1-1 to SL1-5 and the second signal lines SL2-1 to SL2-4 may be connected to the input pads I-PD arranged in the non-display area NDA.

Each of the first signal lines SL1-1 to SL1-5 may be connected to one end of a corresponding one of the first sensing electrodes IE1-1 to IE1-5. Meanwhile, some of the first signal lines SL1-1 to SL1-5 may be connected to one end of the first sensing electrode, and the others thereof may be connected to the other end of the first sensing electrode, but the present disclosure is not limited to an embodiment.

Each of the second signal lines SL2-1 to SL2-4 may be connected to one end of a corresponding one of the second sensing electrodes IE2-1 to IE2-4. Meanwhile, the input sensing layer ISL may further include signal lines connected to the other ends of the second sensing electrodes IE2-1 to IE2-4, but is not limited to an embodiment.

Each of the first sensing electrodes IE1-1 to IE1-5 may include first sensor parts SP1 and first connection parts CP1 arranged in the active area AA. The first sensor parts SP1 may be arranged in the second direction DR2 in the one first sensing electrode. Each of the first connection parts CP1 may connect the first sensor parts SP1 adjacent to each other in the second direction DR2.

Each of the second sensing electrodes IE2-1 to IE2-4 may include second sensor parts SP2 and second connection parts CP2 arranged in the active area AA. The second sensor parts SP2 may be arranged in the first direction DR1 in the one second sensing electrode. Each of the second connection parts CP2 may connect the second sensor parts SP2 adjacent to each other in the first direction DR1.

The first sensor parts SP1 of the first sensing electrodes IE1-1 to IE1-5 and the second sensor parts SP2 and the second connection parts CP2 of the second sensing electrodes IE2-1 to IE2-4 may be formed on the same layer. In the one first sensing electrode, the first sensor parts SP1 may be spaced apart from each other with the second sensing electrodes IE2-1 to IE2-4 arranged on the same layer and interposed therebetween. The first connection parts CP1 may be formed on a layer different from that of the first sensor parts SP1 and may overlap the first sensor parts SP1 on a plane. The first connection parts CP1 may be electrically connected to the overlapping first sensor parts SP1 and may electrically connect the adjacent first sensor parts SP1.

Each of the first sensing electrodes IE1-1 to IE1-5 and the second sensing electrodes IE2-1 to IE2-4 may have a mesh shape. The first sensing electrodes IE1-1 to IE1-5 and the second sensing electrodes IE2-1 to IE2-4 have a mesh shape, and thus parasitic capacitances with electrodes of the display panel DP (see FIG. 6) may be reduced. Further, the first sensing electrodes IE1-1 to IE1-5 and the second sensing electrodes IE2-1 to IE2-4 may not overlap light emitting areas of the display panel DP (see FIG. 6), and accordingly, the sensing electrodes may be prevented from being visually recognized from an outside of the display device DD.

Each of the first sensing electrodes IE1-1 to IE1-5 and the second sensing electrodes IE2-1 to IE2-4 may include silver, aluminum, copper, chromium, nickel, titanium, etc., which may be processed at a low temperature. Accordingly, even when the input sensing layer ISL is formed on the display panel DP in a continuous process, a low-temperature process may be performed to prevent damage to light emitting elements of the display panel DP. However, the materials of the first sensing electrodes IE1-1 to IE1-5 and the second sensing electrodes IE2-1 to IE2-4 are not limited to the above example.

FIG. 7 illustrates, by way of example, the first sensing electrodes IE1-1 to IE1-5 and the second sensing electrodes IE2-1 to IE2-4 according to an embodiment, and shapes of the sensing electrodes are not limited thereto. In an embodiment, the first sensing electrodes IE1-1 to IE1-5 and the second sensing electrodes IE2-1 to IE2-4 may have a shape (e.g., a bar shape) in which the sensor parts and the connection parts are not distinguished from each other. Further, FIG. 7 illustrates, by way of example, the first sensor parts SP1 and the second sensor parts SP2 having a rhombus shape, but shapes of the first sensor parts SP1 and the second sensor parts SP2 are not limited thereto, and may be various polygonal shapes.

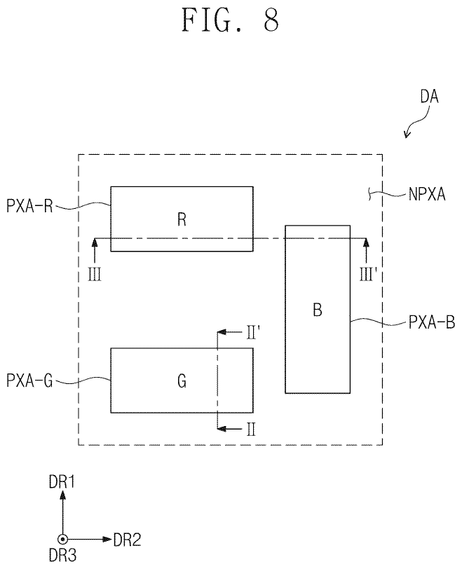

FIG. 8 is an enlarged plan view of a portion of a display area of the display panel according to an embodiment of the present disclosure.

Referring to FIG. 8, the display area DA may include a first light emitting area PXA-R, a second light emitting area PXA-G, and a third light emitting area PXA-B and a non-light emitting area NPXA surrounding the first light emitting area PXA-R, the second light emitting area PXA-G, and the third light emitting area PXA-B. The first light emitting area PXA-R, the second light emitting area PXA-G, and the third light emitting area PXA-B may correspond to areas through which light provided from the light emitting elements is emitted. The first light emitting area PXA-R, the second light emitting area PXA-G, and the third light emitting area PXA-B may be classified according to colors of light emitted toward an outside of the display module DM (see FIG. 4).

The first light emitting area PXA-R, the second light emitting area PXA-G, and the third light emitting area PXA-B may provide first color light, second color light, and third color light having different colors. For example, the first color light may be a red light, the second color light may be a green light, and the third color light may be a blue color. However, an example of the first color light, the second color light, and the third color light is not necessarily limited to the above example.

Each of the first light emitting area PXA-R, the second light emitting area PXA-G, and the third light emitting area PXA-B may be defined as an area in which an upper surface of an anode is exposed by a light emitting opening, which will be described below. The non-light emitting area NPXA may set the boundaries of the first light emitting area PXA-R, the second light emitting area PXA-G, and the third light emitting area PXA-B and may prevent color mixing between the first light emitting area PXA-R, the second light emitting area PXA-G, and the third light emitting area PXA-B.

Each of the first light emitting area PXA-R, the second light emitting area PXA-G, and the third light emitting area PXA-B may be provided in plurality and may be repeatedly disposed in the display area DA to have a predetermined arrangement shape. For example, the first light emitting area PXA-R, the second light emitting area PXA-G, and the third light emitting area PXA-B may be grouped into one pixel unit and alternately arranged in the first direction DR1 and the second direction DR2.

Meanwhile, FIG. 8 illustrates, by way of example, arrangement of the first light emitting area PXA-R, the second light emitting area PXA-G, and the third light emitting area PXA-B, and the present disclosure is not limited thereto, and the first light emitting area PXA-R, the second light emitting area PXA-G, and the third light emitting area PXA-B may be arranged in various forms. In an embodiment, the first light emitting area PXA-R, the second light emitting area PXA-G, and the third light emitting area PXA-B may have a PENTILE™ arrangement form. Alternatively, the first light emitting area PXA-R, the second light emitting area PXA-G, and the third light emitting area PXA-B may have a stripe arrangement form or a Diamond Pixel™ arrangement form.

The first light emitting area PXA-R, the second light emitting area PXA-G, and the third light emitting area PXA-B may have various shapes on a plane. For example, the first light emitting area PXA-R, the second light emitting area PXA-G, and the third light emitting area PXA-B may have a polygonal shape, a circular shape, an elliptical shape, or the like. FIG. 4 illustrates, by way of example, the first light emitting area PXA-R, the second light emitting area PXA-G, and the third light emitting area PXA-B having a rectangular shape on a plane.

The first light emitting area PXA-R, the second light emitting area PXA-G, and the third light emitting area PXA-B may have the same shape on a plane or at least portions thereof may have different shapes. The first light emitting area PXA-R, the second light emitting area PXA-G, and the third light emitting area PXA-B may have different areas on a plane. However, the present disclosure is not limited thereto, and the first light emitting area PXA-R, the second light emitting area PXA-G, and the third light emitting area PXA-B may have the same area on a plane. In an embodiment, an area of the first light emitting area PXA-R that emits red light may be the same as an area of the second light emitting area PXA-G that emits green light and may be smaller than an area of the third light emitting area PXA-B that emits blue light.

Meanwhile, the shape, the area, the arrangement, and the like of the first light emitting area PXA-R, the second light emitting area PXA-G, and the third light emitting area PXA-B of the display module DM (see FIG. 2) according to the present disclosure may be variously designed according to the color of the emitted light and the size and configuration of the display module DM (see FIG. 4) and are not limited to an embodiment illustrated in FIG. 8.

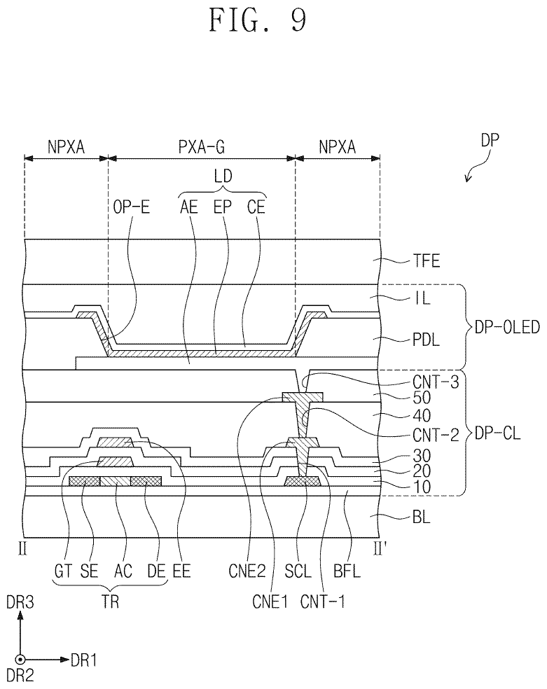

FIG. 9 is a cross-sectional view of the display panel corresponding to line II-II′ of FIG. 8 according to an embodiment of the present disclosure. For example, FIG. 9 is an enlarged view of the second light emitting area PXA-G and the non-light emitting area NPXA around the second light emitting area PXA-G illustrated in FIG. 8.

Referring to FIG. 9, the display panel DP may include the base layer BL, a circuit element layer DP-CL, and a display element layer DP-OLED and an encapsulation layer TFE.

The display panel DP may include a plurality of insulating layers, a semiconductor pattern, a conductive pattern, a signal line, and the like. The insulating layer, a semiconductor layer, and a conductive layer are formed by coating, deposition, or the like. Thereafter, the insulating layer, the semiconductor layer, and the conductive layer may be selectively patterned by photolithography and etching. In this manner, the semiconductor pattern, the conductive pattern, the signal line, and the like included in the circuit element layer DP-CL and the display element layer DP-OLED may be formed.

The circuit element layer DP-CL may be disposed on the base layer BL. The circuit element layer DP-CL may include driving elements, a buffer layer BFL, and first to fifth insulating layers 10, 20, 30, 40, and 50. For easy description, FIG. 9 illustrates a transistor TR, a signal transmission line SCL, and a plurality of connection electrodes CNE1 and CNE2 among the driving elements and illustrates the first to fifth insulating layers 10, 20, 30, 40, and 50 that are sequentially laminated. Meanwhile, this is illustrated by way of example, configurations or an arrangement relationship of the driving elements constituting the circuit element layer DP-CL may be variously changed, and the present disclosure is not limited to an embodiment.

The buffer layer BFL may be disposed on the base layer BL. The buffer layer BFL may improve a coupling force between the base layer BL and the semiconductor pattern. The buffer layer BFL may include a silicon oxide layer and/or a silicon nitride layer. When the buffer layer BFL includes the silicon oxide layer and the silicon nitride layer, the two layers may be alternately laminated.

The transistor TR may be disposed on the buffer layer BFL. The transistor TR may include the semiconductor pattern and a gate electrode GT.

The semiconductor pattern may be disposed on the buffer layer BFL. The semiconductor pattern may include polysilicon. However, the present disclosure is not limited thereto, and the semiconductor pattern may include an amorphous silicon or a metal oxide. FIG. 9 merely illustrates, by way of example, some semiconductor patterns, and one or more semiconductor patterns may be further arranged in the plurality of light emitting areas. The semiconductor pattern may include a plurality of areas that are distinguished according to conductivity.

The semiconductor pattern may include a source area SE, an active area AC, and a drain area DE. The active area AC may be an area having relatively lower electrical conductivity than those of the source area SE and the drain area DE. The source area SE and the drain area DE may be arranged to be spaced apart from each other with the active area AC interposed therebetween.

The gate electrode GT may be disposed between the first insulating layer 10 and the second insulating layer 20. The gate electrode GT may be disposed to overlap the active area AC of the semiconductor pattern. In an embodiment, the transistor TR is illustrated as a top-gate structure by way of example. However, this is illustrated by way of example, the gate electrode GT may be disposed under the semiconductor pattern, and the present disclosure is not limited to an embodiment.

The signal transmission line SCL may be conductive. In an embodiment, the signal transmission line SCL may be disposed on the same layer as the semiconductor pattern. For example, the signal transmission line SCL may be formed simultaneously with the semiconductor pattern. In this case, the signal transmission line SCL may be formed by forming a highly conductive area on the semiconductor pattern through a doping process or the like. By simultaneously forming the signal transmission line SCL and the semiconductor pattern of the transistor TR, a process may be simplified and process costs may be reduced. However, this is described by way of example, the signal transmission line SCL may be formed by patterning a conductive material such as a metal unlike the semiconductor pattern or formed on a layer different from the semiconductor pattern, and the present disclosure is not limited to an embodiment.

The source area SE, the active area AC, the drain area DE, and the signal transmission line SCL of the transistor TR may be covered by the first insulating layer 10. The transistor TR may be covered by the second insulating layer 20.

In an embodiment, the circuit element layer DP-CL may further include an upper electrode EE. The upper electrode EE may be disposed between the second insulating layer 20 and the third insulating layer 30. The upper electrode EE may be covered by the third insulating layer 30. The upper electrode EE may at least partially overlap the gate electrode GT. The upper electrode EE may form a capacitor together with the gate electrode GT. The capacitor may be a storage capacitor constituting a pixel circuit. By further including the upper electrode EE, the capacitor and the transistor TR may be arranged to overlap each other on a plane, thereby improving a degree of integration of the pixel circuit and facilitating design of a high-resolution display panel. However, this is illustrated by way of example, the capacitor may be formed at a position that does not overlap the transistor TR, the upper electrode EE and the gate electrode GT may not form the capacitor, the upper electrode EE may be omitted, and the present disclosure is not limited to an embodiment.

The plurality of connection electrodes CNE1 and CNE2 may be arranged on the buffer layer BFL. The first connection electrode CNE1 may be disposed between the third insulating layer 30 and the fourth insulating layer 40. The first connection electrode CNE1 may be connected to the signal transmission line SCL by a first contact hole CNT-1 formed while passing through the second insulating layer 20 and the third insulating layer 30.

The second connection electrode CNE2 may be disposed between the fourth insulating layer 40 and the fifth insulating layer 50. The second connection electrode CNE2 may be connected to the first connection electrode CNE1 by a second contact hole CNT-2 formed while passing through the fourth insulating layer 40. As a result, the second connection electrode CNE2 may be connected to the signal transmission line SCL. A signal flowing through the signal transmission line SCL may be transmitted to the display element layer DP-OLED through the first connection electrode CNE1 and the second connection electrode CNE2.

The display element layer DP-OLED may be disposed on the circuit element layer DP-CL. The display element layer DP-OLED may include a pixel defining film PDL, a light emitting element LD, and an inorganic layer IL.

The pixel defining film PDL may be disposed on the fifth insulating layer 50 of the circuit element layer DP-CL. A light emitting opening OP-E may be defined by the pixel defining film PDL. The pixel defining film PDL may include an inner surface defining the light emitting opening OP-E. The light emitting opening OP-E may correspond to an anode AE, and the pixel defining film PDL may expose at least a portion of the anode AE through the light emitting opening OP-E.

The pixel defining film PDL may include an inorganic insulating material. For example, the pixel defining film PDL may include a silicon nitride (SiNₓ).

The light emitting element LD may include the anode AE (or a first electrode), a light emitting pattern EP, and a cathode CE (or a second electrode).

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 by a third contact hole CNT-3 defined while passing through the fifth insulating layer 50. Thus, the anode AE may be electrically connected to the signal transmission line SCL through the first connection electrode CNE1 and the second connection electrode CNE2 and thus electrically connected to the corresponding circuit element. The anode AE may include a single-layer structure or a multi-layer structure. The anode AE may include a plurality of layers including ITO and Ag. For example, the anode AE may include a layer including the ITO (hereinafter, referred to as a lower ITO layer), a layer disposed on the lower ITO layer and including Ag (hereinafter, referred to as an Ag layer), and a layer disposed on the Ag layer and including the ITO (hereinafter, referred to as an upper ITO layer). However, the present disclosure is not limited thereto, and the anode AE may be provided as a single layer.

The light emitting pattern EP may be disposed on the anode AE. The light emitting pattern EP may include a light emitting layer including a light emitting material. The light emitting pattern EP may further include a hole injection layer HIL and a hole transport layer HTL arranged between the anode AE and the light emitting layer and may further include an electron transport layer ETL and an electron injection layer EIL arranged on the light emitting layer. The light emitting pattern EP may be referred to as an “organic layer” or an “intermediate layer.” The light emitting pattern EP may cover a portion of an upper surface of the pixel defining film PDL.

The cathode CE may be disposed on the light emitting pattern EP. The cathode CE may be provided as a common layer. The cathode CE may cover the light emitting pattern EP. The cathode CE may receive a driving voltage.

The inorganic layer IL may be disposed on the light emitting element LD. The inorganic layer IL may cover the light emitting element LD and provide a flat upper surface. The inorganic layer IL may include an inorganic material.

The encapsulation layer TFE may be disposed on the inorganic layer IL. The encapsulation layer TFE may include a plurality of thin films. Some thin films may be arranged to improve optical efficiency, and some thin films may be arranged to protect the light emitting element LD. A detailed description thereof will be provided below.

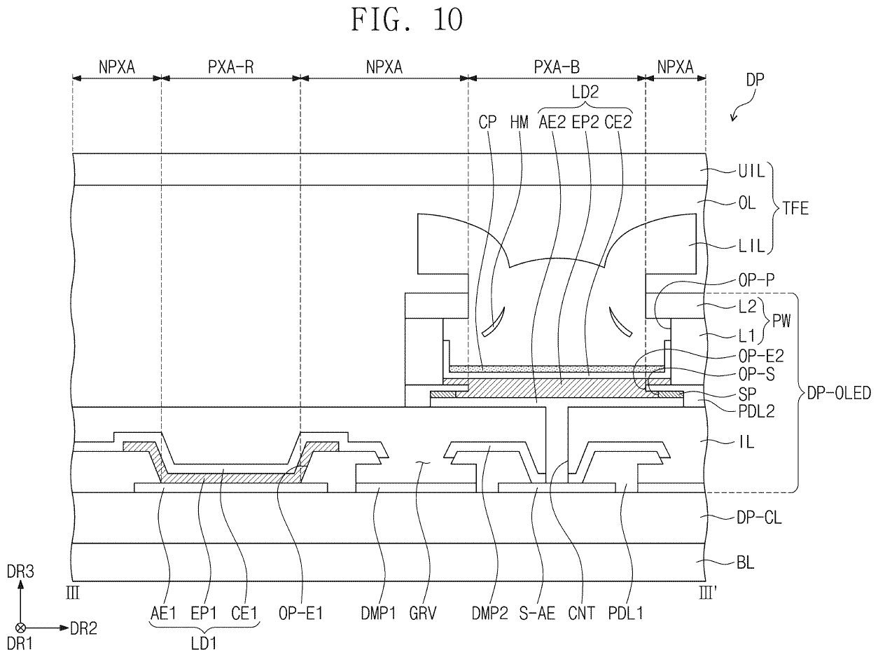

FIG. 10 is a cross-sectional view of the display panel corresponding to line III-III′ of FIG. 8 according to an embodiment of the present disclosure. In description of FIG. 10, the same/similar reference numerals are used for the same/similar components described in FIG. 9, and a duplicated description thereof will be omitted.

Referring to FIG. 10, the display panel DP may include the base layer BL, the circuit element layer DP-CL, the display element layer DP-OLED, and the encapsulation layer TFE. The display element layer DP-OLED may include light emitting elements LD1 and LD2, pixel defining films PDL1 and PDL2, the inorganic layer IL, a sacrificial pattern SP, and a partition wall PW.

The light emitting elements LD1 and LD2 may include the first light emitting element LD1 and the second light emitting element LD2 that emit light having different colors. The first light emitting element LD1 may be provided as a plurality of first light emitting elements LD1, and the second light emitting element LD2 may be provided as a plurality of second light emitting elements LD2. However, for convenience of description, hereinafter, the first light emitting element LD1 and the second light emitting element LD2 are expressed in a singular form. Further, the pixel defining films PDL1 and PDL2 may include the first pixel defining film PDL1 disposed on the circuit element layer DP-CL and the second pixel defining film PDL2 disposed on the inorganic layer IL. The first pixel defining film PDL1 may correspond to the pixel defining film PDL illustrated in FIG. 9. The first light emitting element LD1 may be adjacent to the light emitting element LD (also referred to as a third light emitting element) illustrated in FIG. 9 on a plane.

The first light emitting element LD1 may include a first anode AE1, a first light emitting pattern EP1, and a first cathode CE1. In an embodiment, the first light emitting pattern EP1 may provide red light. A first light emitting opening OP-E1 may be defined in the first pixel defining film PDL1. The first light emitting opening OP-E1 may expose at least a portion of the first anode AE1. In an embodiment, the first light emitting area PXA-R may be defined as an area of an upper surface of the first anode AE1, which is exposed by the first light emitting opening OP-E1.

The display panel DP of the present disclosure may further include a sub-anode S-AE disposed on the circuit element layer DP-CL. The sub-anode S-AE may include the same material as the first anode AE1. The sub-anode S-AE may be connected to the second connection electrode CNE2 by a connection contact hole CNT-3 defined while passing through the fifth insulating layer 50 as in the anode AE illustrated in FIG. 9.

The first pixel defining film PDL1 may define (or have) a groove GRV. The groove GRV may have an inverted tapered shape on a cross section. The display panel DP of the present disclosure may further include a first dummy pattern DMP1 and a second dummy pattern DMP2. The first dummy pattern DMP1 may be disposed in the groove GRV. The second dummy pattern DMP2 may be disposed on the first pixel defining film PDL1. Each of the first dummy pattern DMP1 and the second dummy pattern DMP2 may be formed through the same process as the first cathode CE1. As the groove GRV is formed, the first cathode CE1 may be separated from the second dummy pattern DMP2, and as a result, the first dummy pattern DMP1 may be formed in the groove GRV. The first dummy pattern DMP1 and the second dummy pattern DMP2 may be removed or not formed according to an embodiment.

The second light emitting element LD2 and the second pixel defining film PDL2 may be arranged on the inorganic layer IL. The second light emitting element LD2 may include a second anode AE2, a second light emitting pattern EP2, and a second cathode CE2. In an embodiment, the second light emitting pattern EP2 may provide blue light. A second light emitting opening OP-E2 may be defined in the second pixel defining film PDL2. The second light emitting opening OP-E2 may expose at least a portion of the second anode AE2. In an embodiment, the third light emitting area PXA-B may be defined as an area of an upper surface of the second anode AE2, which is exposed by the second light emitting opening OP-E2.

According to an embodiment of the present disclosure, a contact hole CNT defined while passing through the inorganic layer IL may be defined in the inorganic layer IL, and the second anode AE2 may be electrically connected to the sub-anode S-AE through the contact hole CNT. That is, the second light emitting element LD2 may be electrically connected to the sub-anode S-AE through the contact hole CNT.

The sacrificial pattern SP may be disposed between the second anode AE2 and the second pixel defining film PDL2. The sacrificial pattern SP may define (or have) a sacrificial opening OP-S through which a portion of the upper surface of the second anode AE2 is exposed. The sacrificial opening OP-S may overlap the second light emitting opening OP-E2.

The second light emitting pattern EP2 may be disposed on the second anode AE2. The second light emitting pattern EP2 may be formed by being patterned by a tip portion defined in the partition wall PW. At least a portion of the second light emitting pattern EP2 may be in contact with a side surface of the partition wall PW.

The second cathode CE2 may be disposed on the second light emitting pattern EP2. The second cathode CE2 may be formed by being patterned by the tip portion defined in the partition wall PW. At least a portion of the second cathode CE2 may be in contact with the side surface of the partition wall PW.

The second pixel defining film PDL2 may include the same material as the first pixel defining film PDL1. The second pixel defining film PDL2 may include an inorganic insulating material. For example, the second pixel defining film PDL2 may include a silicon nitride (SiNₓ).

The partition wall PW may be disposed on the second pixel defining film PDL2. The second cathode CE2 may be patterned by the tip portion defined in the partition wall PW. The second cathode CE2 may be disposed in a partition wall opening OP-P defined in the partition wall PW.

In an embodiment of the present disclosure, the display element layer DP-OLED may further include a capping pattern CP. The capping pattern CP may be disposed in the partition wall opening OP-P and may be disposed on the second cathode CE2. The capping pattern CP may be patterned by the tip portion defined by the partition wall PW. In an embodiment, the capping pattern CP may be omitted.

The partition wall PW may include a plurality of layers sequentially laminated. For example, the partition wall PW may include a first partition wall layer L1 and a second partition wall layer L2. The first partition wall layer L1 may be disposed on the second pixel defining film PDL2, and the second partition wall layer L2 may be disposed on the first partition wall layer L1. As illustrated in FIG. 10, a thickness of the first partition wall layer L1 may be greater than a thickness of the second partition wall layer L2, but the present disclosure is not limited thereto.

The first partition wall layer L1 and the second partition wall layer L2 may include a conductive material. For example, the conductive material may include a metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or alloys thereof. The TCO may include an indium tin oxide (ITO), an indium zinc oxide (IZO), a zinc oxide, an indium oxide, an indium gallium oxide, an indium gallium zinc oxide (IGZO) or an aluminum zinc oxide.

The partition wall PW may have an undercut shape on a cross section. At least one of the plurality of layers of the partition wall PW may be recessed as compared to the other layers, and accordingly, the partition wall PW may include the tip portion. For example, the first partition wall layer L1 may have an undercut shape with respect to the second partition wall layer L2. The second partition wall layer L2 may protrude toward the second light emitting opening OP-E2 further than the first partition wall layer L1 to form a tip portion. A portion protruding from the first partition wall layer L1 toward the second light emitting opening OP-E2 may be defined as a tip portion in the partition wall PW. That is, a second inner surface of the second partition wall layer L2 may be closer to a center of the second anode AE2 than a first inner surface of the first partition wall layer L1.

FIG. 10 illustrates, by way of example, that the first inner surface of the first partition wall layer L1 and the second inner surface of the second partition wall layer L2 are perpendicular to an upper surface of the second pixel defining film PDL2, but the present disclosure is not limited thereto. For example, the partition wall PW may have a tapered shape or a reverse tapered shape.

The partition wall PW may receive a driving voltage. The first inner surface of the first partition wall layer L1 may be in contact with the second cathode CE2, so that the second cathode CE2 may be electrically connected to the partition wall PW. As a result, the second cathode CE2 may receive the driving voltage from the partition wall PW. In an embodiment, the first cathode CE1 and the second cathode CE2 may receive different driving voltages.

The second light emitting element LD2 of the present disclosure may be disposed on a different layer from the first light emitting element LD1. The first light emitting element LD1 may be formed using a fine metal mask (FMM), but the second light emitting element LD2 may be formed by being patterned without the FMM. As the FMM is used, a minimum separation distance between the light emitting elements may be reduced, and thus an area of the third light emitting area PXA-B of the second light emitting element LD2 may be increased. As a result, the display panel DP having improved display quality may be provided.

The encapsulation layer TFE may be disposed on the display element layer DP-OLED. The encapsulation layer TFE may include a lower encapsulation inorganic pattern LIL, an encapsulation organic film OL, and an upper encapsulation inorganic film UIL.

The lower encapsulation inorganic pattern LIL may correspond to (or overlap) the second light emitting opening OP-E2. The lower encapsulation inorganic pattern LIL may be disposed on the capping pattern CP to cover the second light emitting element LD2. A portion of the lower encapsulation inorganic pattern LIL may be formed inside the partition wall opening OP-P, and the other portion of the lower encapsulation inorganic pattern LIL may be formed on the partition wall PW.

A groove HM may be defined in the lower encapsulation inorganic pattern LIL. The groove HM of the lower encapsulation inorganic pattern LIL may be spaced apart from the partition wall PW and the second light emitting element LD2. The lower encapsulation inorganic pattern LIL may have a symmetrical shape based on an axis passing through a center of the lower encapsulation inorganic pattern LIL.

The encapsulation organic film OL may be disposed on the lower encapsulation inorganic pattern LIL. The encapsulation organic film OL may cover the lower encapsulation inorganic pattern LIL and provide a flat upper surface. The upper encapsulation inorganic film UIL may be disposed on the encapsulation organic film OL. The lower encapsulation inorganic pattern LIL and the upper encapsulation inorganic film UIL may protect the display element layer DP-OLED from moisture/oxygen, and the encapsulation organic film OL may protect the display element layer DP-OLED from foreign substances such as dust particles.

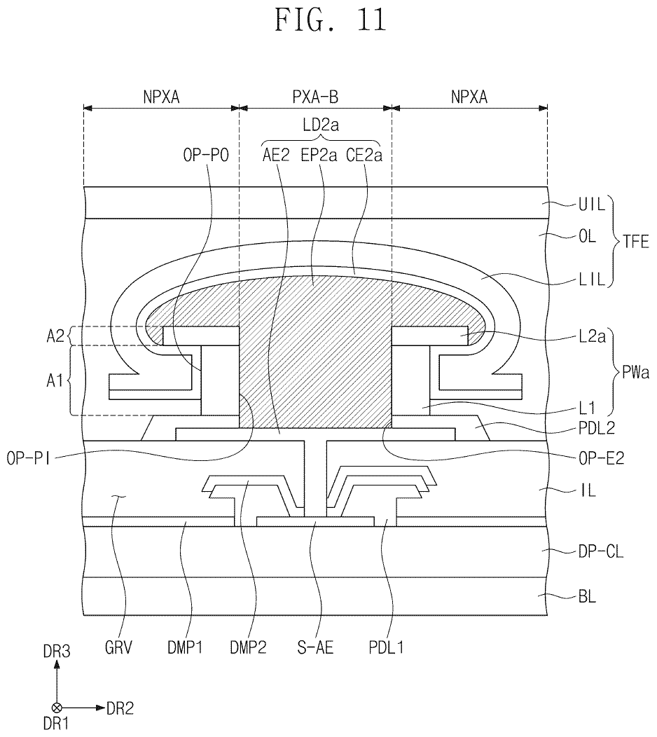

FIG. 11 is a cross-sectional view of a portion of the display panel according to an embodiment of the present disclosure. In detail, FIG. 11 is an enlarged view of a second light emitting element LD2a according to an embodiment. In description of FIG. 11, the same/similar reference numerals are used for the same/similar components described in FIG. 10, and a duplicated description thereof will be omitted.

Referring to FIG. 11, an outer partition wall opening OP-PO of a partition wall PWa may have an undercut shape on a cross section. The partition wall PWa may include a plurality of layers sequentially laminated, and at least one of the plurality of layers may be recessed compared to other layers. Accordingly, the partition wall PWa may include a tip portion.

The partition wall PWa may include the first partition wall layer L1 and a second partition wall layer L2a. An inner surface of the first partition wall layer L1 and an inner surface of the second partition wall layer L2a defining an inner partition wall opening OP-PI may be aligned with each other. That is, the inner partition wall opening OP-PI may be an opening formed by continuously forming the inner surface of the first partition wall layer L1 and the inner surface of the second partition wall layer L2a rather than a protruding shape.

The first partition wall layer L1 may be relatively recessed compared to the second partition wall layer L2a with respect to the non-light emitting area NPXA. The first partition wall layer L1 may be formed to be undercut with respect to the second partition wall layer L2a. A portion of the second partition wall layer L2a, which protrudes from the first partition wall layer L1 toward a center of the outer partition wall opening OP-PO, may be defined as the tip portion in the partition wall PWa.

The outer partition wall opening OP-PO may include a first area A1 defined by an outer surface of the first partition wall layer L1 and a second area A2 defined by an outer surface of the second partition wall layer L2a. The first area A1 and the second area A2 may be integrally formed openings. A width of the first area A1 may be different from a width of the second area A2. For example, a length of the first area A1 in one direction (e.g., the second direction DR2) may be greater than a length of the second area A2 in the one direction. The one direction may be perpendicular to a thickness direction (e.g., the third direction DR3) of the circuit element layer DP-CL. That is, the second area A2 of the outer partition wall opening OP-PO may be an area defining the tip portion. The second partition wall layer L2a protrudes farther than the first partition wall layer L1 in one direction (e.g., the second direction DR2). The second area A2 may have a smaller width than that of the first area A1 due to the protruding tip portion.

The second light emitting element LD2a may be disposed on the inorganic layer IL. The second light emitting element LD2a may include the second anode AE2, a second light emitting pattern EP2a, and a second cathode CE2a. In an embodiment, the second light emitting pattern EP2a may provide blue light.

The second light emitting pattern EP2a may be formed by being patterned by the tip portion defined in the partition wall PWa. The second light emitting pattern EP2a may be formed on the second anode AE2 to cover a portion of the partition wall PWa. For example, the second light emitting pattern EP2a may be patterned by the tip portion defined in the partition wall PWa to cover an outer surface of the second partition wall layer L2a.

The second cathode CE2a may be formed by being patterned by the tip portion defined in the partition wall PWa. The second cathode CE2a may cover the second light emitting pattern EP2a. The second cathode CE2a may be patterned by the tip portion defined in the partition wall PWa to cover at least a portion of the outer surface of the first partition wall layer L1. The second cathode CE2a may be in contact with at least a portion of the outer surface of the first partition wall layer L1 to receive the driving voltage from the partition wall PWa.

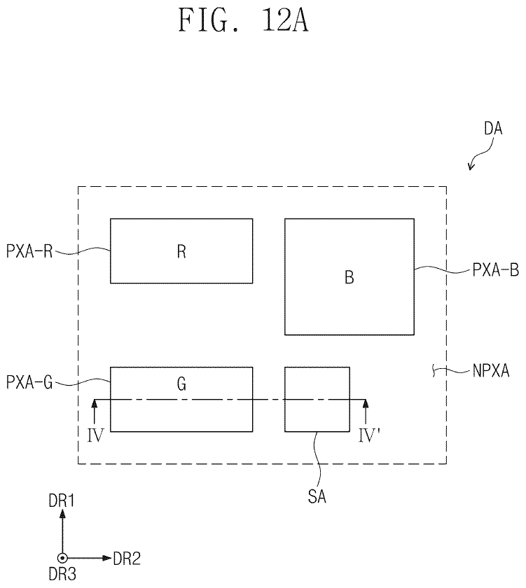

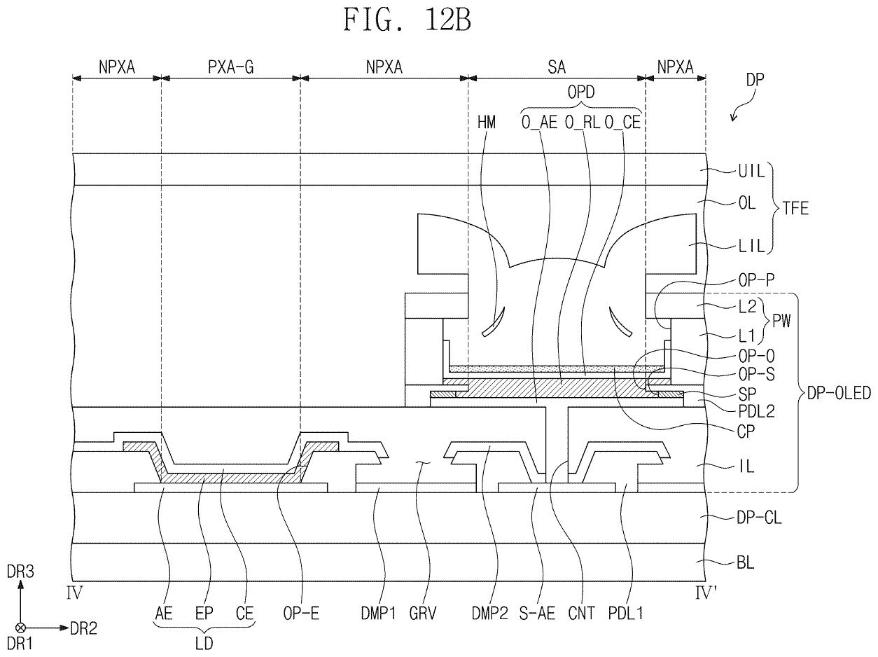

FIG. 12A is an enlarged plan view of a portion of the display area of the display panel according to an embodiment of the present disclosure. FIG. 12B is a cross-sectional view of the display device corresponding to line IV-IV′ illustrated in FIG. 12A according to an embodiment of the present disclosure.

Referring to FIGS. 12A and 12B together, the display area DA may include the first light emitting area PXA-R, the second light emitting area PXA-G, the third light emitting area PXA-B, a sensing area SA, and the non-light emitting area NPXA surrounding the first light emitting area PXA-R, the second light emitting area PXA-G, the third light emitting area PXA-B, and the sensing area SA.

According to an embodiment of the present disclosure, a light receiving element OPD and the second pixel defining film PDL2 may be arranged on the inorganic layer IL. The light receiving element OPD may include a sensing anode electrode O_AE, a photoelectric conversion layer O_RL, and a sensing cathode electrode O_CE. The sensing anode electrode O_AE may be referred to as a first sensing electrode, and the sensing cathode electrode O_CE may be referred to as a second sensing electrode.

A light receiving opening OP-O may be defined in the second pixel defining film PDL2. The light receiving opening OP-O of the second pixel defining film PDL2 exposes at least a portion of the sensing anode electrode O_AE. The photoelectric conversion layer O_RL is disposed on the sensing anode electrode O_AE exposed by the light receiving opening OP-O. The photoelectric conversion layer O_RL may include an organic photo-sensing material. The sensing cathode electrode O_CE may be disposed on the photoelectric conversion layer O_RL.

The sensing anode electrode O_AE may be electrically connected to the sub-anode S-AE through the contact hole CNT. The photoelectric conversion layer O_RL and the sensing cathode electrode O_CE may be formed by being patterned by the tip portion defined in the partition wall PW. The sensing cathode electrode O_CE may be in contact with the first partition wall layer L1 of the partition wall PW. The sensing cathode electrode O_CE may receive the driving voltage from the partition wall PW. The sensing area SA may be an area in which the photoelectric conversion layer O_RL is disposed.

When light emitted from the light emitting element LD of the present disclosure is incident on the light receiving element OPD, the light receiving element OPD may generate photocharges to sense an external gesture or the like.

The light receiving element OPD of the present disclosure may be disposed on the inorganic layer IL and disposed on a layer different from the light emitting element LD. As a result, the degree of freedom of arrangement of the light receiving element OPD may be increased, and thus the display panel DP having improved reliability may be provided.

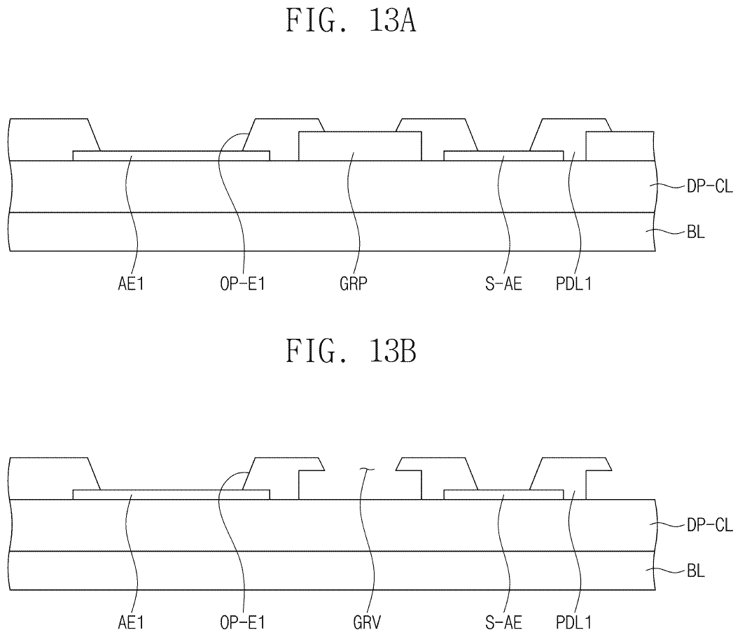

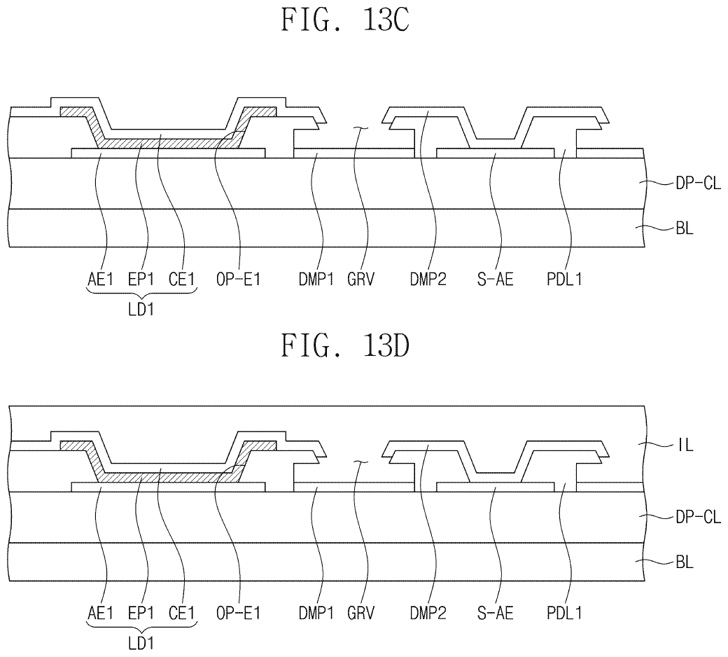

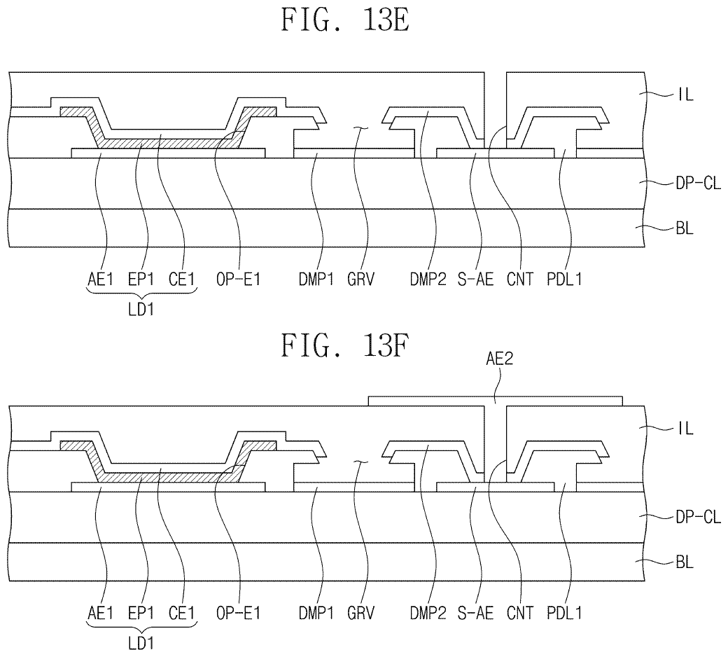

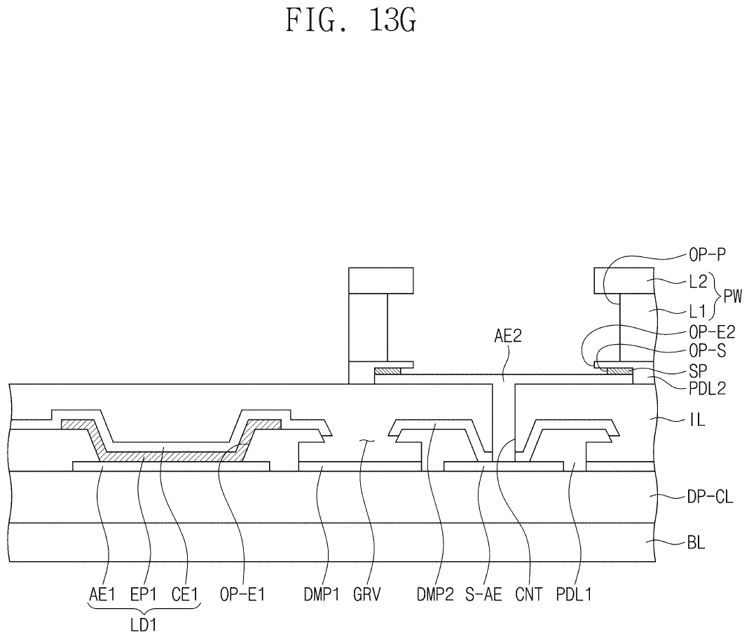

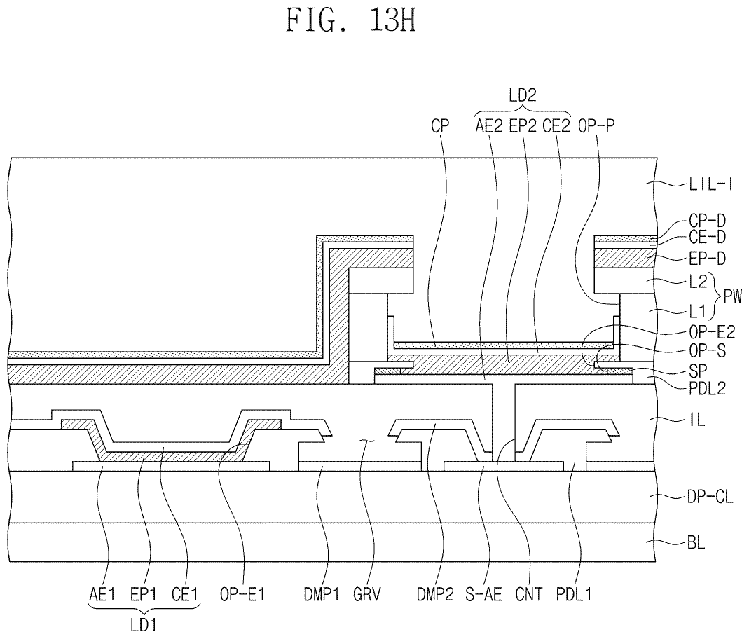

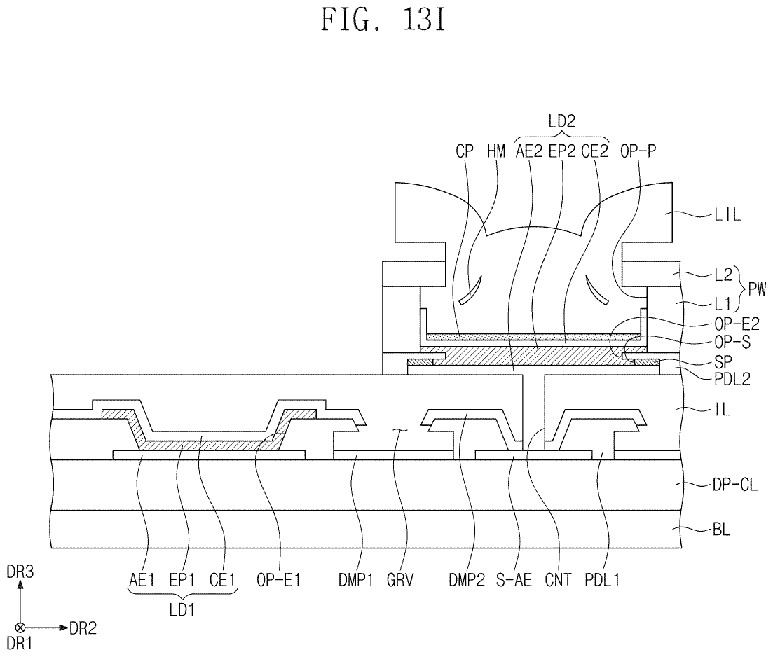

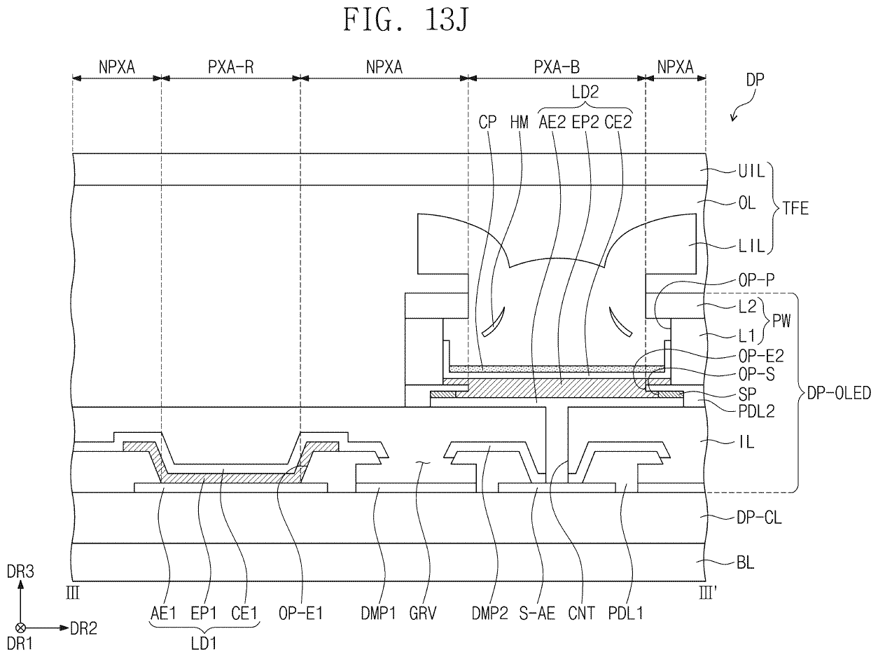

FIGS. 13A to 13J are cross-sectional views illustrating some of operations of a method of manufacturing a display panel according to an embodiment of the present disclosure.

Referring to FIG. 13A, an operation of forming the base layer BL, an operation of forming the circuit element layer DP-CL on the base layer BL, and an operation of forming the first anode AE1, the sub-anode S-AE, the first pixel defining film PDL1, and a groove pattern GRP on the circuit element layer DP-CL may be performed. The first light emitting opening OP-E1, through which at least a portion of the first anode AE1 is exposed, may be defined in the first pixel defining film PDL1.

The groove pattern GRP may be formed before the first pixel defining film PDL1 is formed. That is, the first pixel defining film PDL1 may be formed on the groove pattern GRP.

Referring to FIG. 13B, an operation of removing the groove pattern GRP to form the groove GRV may be performed. The operation of removing the groove pattern GRP may be performed through an operation of wet etching the groove pattern GRP using a photoresist pattern. As a result, the groove GRV corresponding to the groove pattern GRP may be formed in the first pixel defining film PDL1.

Referring to FIG. 13C, an operation of forming the first light emitting element LD1 may be performed. In detail, the first light emitting pattern EP1 may be formed on the first anode AE1, and the first cathode CE1 may be formed on the first light emitting pattern EP1. Although not illustrated, the first light emitting pattern EP1 may be formed through the FMM.

The first cathode CE1 may be provided as a common layer. An operation of forming the first cathode CE1 may include a process of depositing a cathode layer. In an embodiment, the process of depositing a cathode layer may be a thermal evaporation process. However, this is by way of example, and the process of depositing a cathode layer is not limited to the above example. The cathode layer may be separated by a tip portion formed in the groove GRV to form the first cathode CE1, the first dummy pattern DMP1, and the second dummy pattern DMP2. The first dummy pattern DMP1 may be disposed in the groove GRV. The second dummy pattern DMP2 may be disposed on the first pixel defining film PDL1.

In an embodiment, the first cathode CE1 of the first light emitting element LD1 in FIG. 10 and the cathode CE of the light emitting element LD in FIG. 9 may be electrically connected to each other, but example embodiments are not limited thereto.

Thereafter, referring to FIGS. 13D and 13E together, an operation of forming the inorganic layer IL on the first cathode CE1 and an operation of forming the contact hole CNT on the inorganic layer IL may be performed.

Referring to FIG. 13F, an operation of forming the second anode AE2 on the inorganic layer IL may be performed. The second anode AE2 may be electrically connected to the sub-anode S-AE through the contact hole CNT formed in the inorganic layer IL.

Thereafter, referring to FIG. 13G, an operation of forming the second pixel defining film PDL2 on the inorganic layer IL, an operation of forming the partition wall PW on the second pixel defining film PDL2, and an operation of forming the sacrificial pattern SP on the second anode AE2 may be performed. The second light emitting opening OP-E2, through which the portion of the upper surface of the second anode AE2 is exposed, may be defined in the second pixel defining film PDL2.

Although not illustrated, the operation of forming the partition wall PW may include an operation of forming the first partition wall layer L1 and the second partition wall layer L2 by etching a first preliminary partition wall layer and a second preliminary partition wall layer. The first partition wall layer L1 and the second partition wall layer L2 may be formed by dry etching and wet etching the first preliminary partition wall layer and the second preliminary partition wall layer using a photoresist layer as a mask.

The wet etching process in an embodiment may be performed in an environment in which an etching selection ratio of the first preliminary partition wall layer and the second preliminary partition wall layer is high. Accordingly, the partition wall PW in which the partition wall opening OP-P is defined may have an undercut shape on a cross section.

The sacrificial pattern SP may define the sacrificial opening OP-S through which the portion of the upper surface of the second anode AE2 is exposed. The sacrificial opening OP-S may overlap the second light emitting opening OP-E2.

Thereafter, referring to FIG. 13H, an operation of forming the second light emitting element LD2 may be performed. In detail, an operation of forming the second light emitting pattern EP2 on the second anode AE2 and an operation of forming the second cathode CE2 on the second light emitting pattern EP2 may be performed.

The operation of forming the second light emitting pattern EP2 may include a process of depositing a light emitting layer. In an embodiment, the process of depositing a light emitting layer may be a thermal evaporation process. However, this is by way of example, and the process of depositing a light emitting layer is not limited to the above example. The light emitting layer may be separated by the tip portion formed in the partition wall PW to form the second light emitting pattern EP2 and a dummy light emitting pattern EP-D.

The operation of forming the second cathode CE2 may include the process of depositing a cathode layer. In an embodiment, the process of depositing a cathode layer may be a thermal evaporation process. However, this is by way of example, and the process of depositing a cathode layer is not limited to the above example. The cathode layer may be separated by the tip portion formed in the partition wall PW to form the second cathode CE2 and a dummy cathode pattern CE-D. The second cathode CE2 may be in contact with the first partition wall layer L1 to receive the driving voltage from the partition wall PW.

In the present disclosure, since only the second light emitting element LD2 is formed through the partition wall PW without using the FMM, a process of manufacturing the display panel DP (see FIG. 4) may be simplified as compared to the disclosure in which all light emitting elements are formed through the partition wall PW without using the FMM.

The method of manufacturing the display panel DP (see FIG. 4) of the present disclosure may further include an operation of forming the capping pattern CP. The capping pattern CP may include a process of depositing a capping layer. In an embodiment, the process of depositing a capping layer may be a thermal evaporation process. The capping layer may be separated by the tip portion formed in the partition wall PW to form the capping pattern CP and a dummy capping pattern CP-D.

Thereafter, an operation of forming a lower encapsulation inorganic layer LIL-I on the second light emitting element LD2 may be performed. The lower encapsulation inorganic layer LIL-I may be formed through a deposition process. In an embodiment, the lower encapsulation inorganic layer LIL-I may be formed through a chemical vapor deposition (CVD) process.

Referring to FIG. 13I, an operation of forming the lower encapsulation inorganic pattern LIL by etching the lower encapsulation inorganic layer LIL-I (see FIG. 13H) may be performed. Although not illustrated, the lower encapsulation inorganic pattern LIL may be formed by dry etching the lower encapsulation inorganic layer LIL-I using a photoresist layer as a mask. During a process of depositing the lower encapsulation inorganic layer LIL-I, the groove HM may be formed in a structure in which an inside of the partition wall opening OP-P is filled. The groove HM may be spaced apart from the partition wall PW.

Thereafter, referring to FIG. 13J, an operation of completing the display panel DP by forming the encapsulation organic film OL and the upper encapsulation inorganic film UIL may be included. The encapsulation organic film OL may be formed by applying an organic material in an inkjet method, but the present disclosure is not limited thereto. The encapsulation organic film OL provides a flattened upper surface. The encapsulation organic film OL may fill a dummy area. However, this is by way of example, and the present disclosure is not limited to the above example. For example, the encapsulation organic film OL may not fill the dummy area or may fill only a portion of the dummy area.

Thereafter, the upper encapsulation inorganic film UIL may be formed by depositing an inorganic material. Therefore, the display panel DP including the base layer BL, the circuit element layer DP-CL, the display element layer DP-OLED, and the encapsulation Layer TFE may be formed.

A display panel of the present disclosure may include a first light emitting element formed using an FMM and a second light emitting element disposed on a different layer from the first light emitting element. The second light emitting element may be formed by being patterned through a partition wall without an FMM. As the FMM is used, a minimum separation distance between the light emitting elements may be reduced, and thus an area of a light emitting area of the second light emitting element may be increased. As a result, the display panel having improved display quality and a simplified manufacturing process may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

Thus, the technical scope of the present disclosure is not limited to the detailed description of the specification but should be defined by the appended claims.

What is claimed is:

1. A display panel comprising:
a base layer;
a first pixel defining film on the base layer and including a first light emitting opening;
a first light emitting element including a first anode on the base layer, a first light emitting pattern in the first light emitting opening, and a first cathode on the first light emitting pattern;
an inorganic layer covering the first light emitting element;
a second pixel defining film on the inorganic layer and including a second light emitting opening;
a partition wall on the second pixel defining film and including a partition wall opening overlapping the second light emitting opening; and
a second light emitting element including a second anode on the inorganic layer, a second light emitting pattern in the second light emitting opening, and a second cathode in contact with the partition wall.

2. The display panel of claim 1, further comprising:
a sub-anode on the base layer, wherein
the inorganic layer includes a contact hole, and
the second anode is electrically connected to the sub-anode through the contact hole in the inorganic layer.

3. The display panel of claim 1, further comprising:
a lower encapsulation inorganic pattern covering the second light emitting element, wherein
the lower encapsulation inorganic pattern has a groove spaced apart from the partition wall and the second light emitting element.

4. The display panel of claim 3, further comprising:
an organic layer covering the inorganic layer and the lower encapsulation inorganic pattern; and
an upper encapsulation inorganic layer disposed on the organic layer.

5. The display panel of claim 1, wherein the second cathode is configured to receive a common voltage from the partition wall.

6. The display panel of claim 1, wherein
the partition wall includes a first partition wall layer and a second partition wall layer on the first partition wall layer, and
the second cathode is in contact with the first partition wall layer.

7. The display panel of claim 6, wherein the first partition wall layer and the second partition wall layer have an undercut shape with respect to the partition wall opening.

8. The display panel of claim 6, wherein
a first area is defined by an outer surface of the first partition wall layer,
a second area is defined by an outer surface of the second partition wall layer,
wherein the second partition wall layer protrudes farther than the first partition wall layer in a first direction, and
a length of the first area in the first direction is greater than a length of the second area in the first direction.
a length of the first area in a first direction is greater than a length of the second area in the first direction.

9. The display panel of claim 8, wherein an inner surface of the first partition wall layer and an inner surface of the second partition wall layer, which define the partition wall opening, are aligned with each other.

10. The display panel of claim 1, further comprising:
a third light emitting element adjacent to the first light emitting element on a plane,
wherein the third light emitting element includes a third anode on the base layer, a third light emitting pattern on the third anode, and a third cathode on the third light emitting pattern.

11. The display panel of claim 10, wherein the first cathode and the third cathode are electrically connected to each other.

12. The display panel of claim 10, wherein
the first anode and the third anode are on a same layer, and
the first light emitting pattern and the third light emitting pattern are on the same layer.

13. The display panel of claim 10, further comprising:
a light receiving element adjacent to the third light emitting element on a plane,
wherein the light receiving element includes a first sensing electrode on the inorganic layer, a photoelectric conversion layer on the first sensing electrode, and a second sensing electrode on the photoelectric conversion layer.

14. The display panel of claim 1, wherein the first pixel defining film includes a groove adjacent to the second light emitting element.

15. The display panel of claim 14, wherein a cross-section of the groove has an inverted tapered shape.

16. The display panel of claim 14, further comprising:
a dummy pattern in the groove,
wherein the inorganic layer is in contact with the dummy pattern.

17. An electronic device comprising:
a display panel configured to display an image; and
a processor configured to provide image data to the display panel,
wherein the display panel includes
a base layer,
a first pixel defining film on the base layer and including a first light emitting opening,
a first light emitting element including a first anode on the base layer, a first light emitting pattern in the first light emitting opening, and a first cathode on the first light emitting pattern,
an inorganic layer covering the first light emitting element,
a second pixel defining film on the inorganic layer and including a second light emitting opening,
a partition wall on the second pixel defining film and including a partition wall opening overlapping the second light emitting opening, and
a second light emitting element including a second anode on the inorganic layer, a second light emitting pattern in the second light emitting opening, and a second cathode in contact with the partition wall.

18. A method of manufacturing a display panel, the method comprising:
forming a first anode and a sub-anode on a base layer;
forming a first pixel defining film that exposes the first anode and the sub-anode;
forming a first light emitting pattern and a first cathode on the first anode;
forming an inorganic layer on the sub-anode, the inorganic layer including a contact hole through which at least a portion of the sub-anode is exposed;
forming a second anode electrically connected to the sub-anode through the contact hole of the inorganic layer;
forming a second pixel defining film on the inorganic layer, the second pixel defining film exposing the second anode;
forming a partition wall on the second pixel defining film, the partition wall including a partition wall opening overlapping the second anode; and
forming a second light emitting pattern and a second cathode in the partition wall opening,
wherein the second cathode is in contact with the partition wall.

19. The method of claim 18, further comprising:
forming a groove in the first pixel defining film adjacent to the second anode on a plane,
wherein a cross-section of the groove has an inverted tapered shape.

20. The method of claim 18, further comprising:
depositing a lower encapsulation inorganic layer, the lower encapsulation inorganic layer covering the partition wall and the second cathode; and
forming a lower encapsulation inorganic pattern corresponding to the partition wall opening by etching the lower encapsulation inorganic layer using a photoresist pattern.
